(19) United States
(12) Patent Application Publication
(10) Pub. No.: US 2006/0141719 A1
(43) Pub. Date: Jun. 29, 2006

(54) Method of fabricating semiconductor device

(76) Inventor: Myung Jin Jung, Seoul (KR)

Correspondence Address: MCKENNA LONG & ALDRIDGE LLP;Song K. Jung, 1900 K Street, N.W., Washington, DC, 20006, US

(21) Appl. No.: 11/312,504

(22) Filed: Dec. 21, 2005

(30) Foreign Application Priority Data
Dec. 29, 2004 (KR) 2004-0114611

(51) Int. Cl. H01L 21/336; H01L 21/311

(52) U.S. Cl. 438/299; 438/694

(57) ABSTRACT

A gate is formed on a predetermined area of a substrate. A spacer insulating layer is formed on sidewalls of the gate. An insulating interlayer is formed over the substrate including the gate and the spacer insulating layer. Polymer generation is simultaneously carried out on a lateral side of the spacer while carrying out a dry etching process on the insulating interlayer. A sidewall spacer is left on both of the sidewalls of the polysilicon gate by performing wet etching to the insulating interlayer and the spacer insulating layer.

### CROSS REFERENCE TO RELATED APPLICATIONS

This application claims the benefit of Korean Patent Application No. 10-2004-0114611, filed on Dec. 29, 2004, which is hereby incorporated by reference as if fully set forth herein.

### BACKGROUND OF THE INVENTION

1. Field of the Invention

The present invention relates to a semiconductor device, and more particularly, to a method of fabricating a semiconductor device. Although the present invention is suitable for a wide scope of applications, it is particularly suitable for enhancing a step of forming a sidewall.

2. Discussion of the Related Art

A substrate for fabricating a semiconductor device is mainly divided into a non-salicide area and a salicide area.

The non-salicide area is used as a resistance area. The salicide area is defined as an area for forming a gate, drain and source of a transistor to be brought into contact with metal. The salicide area requires low resistance.

The salicide and non-salicide areas are implemented by wet etch. However, during the wet etch, some oxide is removed from the resistance area, thereby ultimately resulting in the salicidation of the resistance area. Hence, the resistance of the resistance area is affected and so is the corresponding semiconductor characteristics. Moreover, in a transistor area, wet etching causes an undercut in the gate and/or the source or drain region which results in a leakage source that changes the transistor's characteristics.

FIGS. 1A-1F illustrate a semiconductor fabricating method according to the related art.

Referring to FIG. 1A, a gate insulating layer 11 is deposited on a substrate 10. A polysilicon gate 13 is formed on a predetermined portion of the gate insulating layer 11. A first spacer 14 is formed on a sidewall of the polysilicon gate 13 and the gate insulating layer 11 that is not overlapped with the polysilicon gate 13. The first spacer 14 is formed by low-pressure tetra-ethyl-ortho-silicate deposition. Source/drain regions (not shown) are formed on the substrate 10 at opposite sides of the polysilicon gate 13. A second spacer 15 is deposited on the first spacer 14 to be overlapped with lateral sides of the polysilicon gate 13. In doing so, the second spacer 15 is formed of silicon nitride (SiN).

Referring to FIG. 1B, a first insulating interlayer 16 is deposited over the substrate including the polysilicon gate 13 and the first and second spacers 14 and 15. In doing so, the first insulating interlayer 16 is formed by plasma-enhanced tetra-ethyl-ortho-silicate deposition.

Referring to FIG. 1C, dry etching is carried out on the first insulating interlayer 16 using a predetermined mask defining a salicide area and a non-salicide area. As a result, the remaining first insulating interlayer 16a has about 75% of the original thickness of the deposited first insulating interlayer 16. In doing so, the first insulating interlayer deposited on the substrate 10 around the first spacer 15 can be almost removed.

Referring to FIG. 1D, a second insulating interlayer 17 is deposited over the substrate 10 including the first insulating interlayer 16a. In doing so, the second insulating interlayer 17 is formed by low-pressure tetra-ethyl-ortho-silicate deposition or atomic layer deposition.

Referring to FIG. 1E, by removing the second insulating interlayer 17 and the remaining first insulating interlayer 16a on the polysilicon gate 13 and by removing the second insulating interlayer 17a on a rest area to a predetermined thickness, a portion of the second insulating interlayer 17a facing the sidewall of the polysilicon gate remains. In doing so, the first and second insulating interlayers are removed by dry etch.

Referring to FIG. 1F, wet etch is carried out on the second insulating interlayer 17a to remove the second insulating layer 17 and the first spacer material 14 from all areas other than the areas of the first and second spacers 14a and 15, which are provided to the sidewall of the polysilicon gate 13. Since the first spacer material 14 and the second insulating interlayer 17 are formed of the same material, the first spacer 14a on the substrate 10 is etched to be indented inwardly from the first insulating interlayer 16b on the second spacer 15 due to the isotropic characteristic of the wet etch.

In fabricating the semiconductor device by the related art method, the second insulating interlayer is re-deposited and then wet etching is carried out, to compensate for the loss caused by the salicide attack and to reduce the occurrence of voids (undercutting) and thus attain a more reliable transistor exhibiting greater resistance stability. The undercut and loss due to wet etching are compensated by re-deposition of the second insulating interlayer prior to the wet etching to prevent the oxide loss caused by undercutting the active area. However, the additional step of redepositing the second insulating interlayer complicates the process and increases production costs.

### SUMMARY OF THE INVENTION

Accordingly, the present invention is directed to a method of fabricating a semiconductor device that substantially obviates one or more problems due to limitations and disadvantages of the related art.

One advantage of the present invention is that it provides a method of fabricating a semiconductor device, by which a more precise and more highly integrated device can be realized by enhancing a sidewall formation.

Additional advantages, and features of the invention will be set forth in part in the description which follows, and in part will become apparent to those having ordinary skill in the art upon examination of the following or may be learned from practice of the invention.

To achieve these objects and other advantages in accordance with the purpose of the invention, as embodied and broadly described herein, a method of fabricating a semiconductor device comprises forming a gate on a predetermined area of a substrate; forming a spacer insulating layer on sidewalls of the gate; forming an insulating interlayer over the substrate including the gate and the spacer insulating layer; simultaneously carrying out polymer generation on a lateral side of the spacer and a dry etching process on the insulating interlayer; and leaving a sidewall spacer on both of the sidewalls of the polysilicon gate by performing wet etching to the insulating interlayer and the spacer insulating layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principle of the invention.

In the drawings:

FIGS. 1A-1F are cross-sectional diagrams of a semiconductor device, respectively illustrating steps of a method for fabricating the device according to a related art; and

FIGS. 2A-2D are cross-sectional diagrams of a semiconductor device, respectively illustrating steps of a method for fabricating the device according to an embodiment of the present invention.

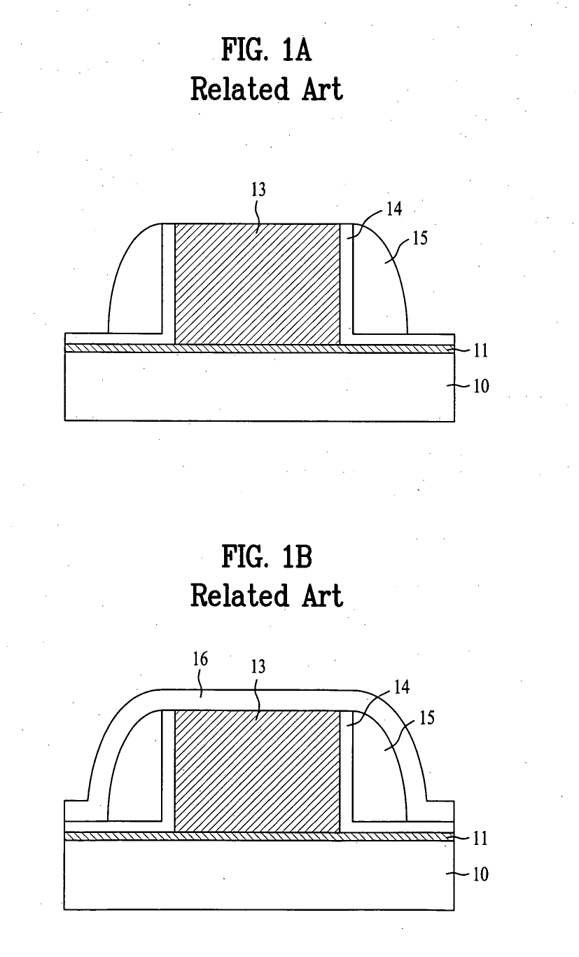

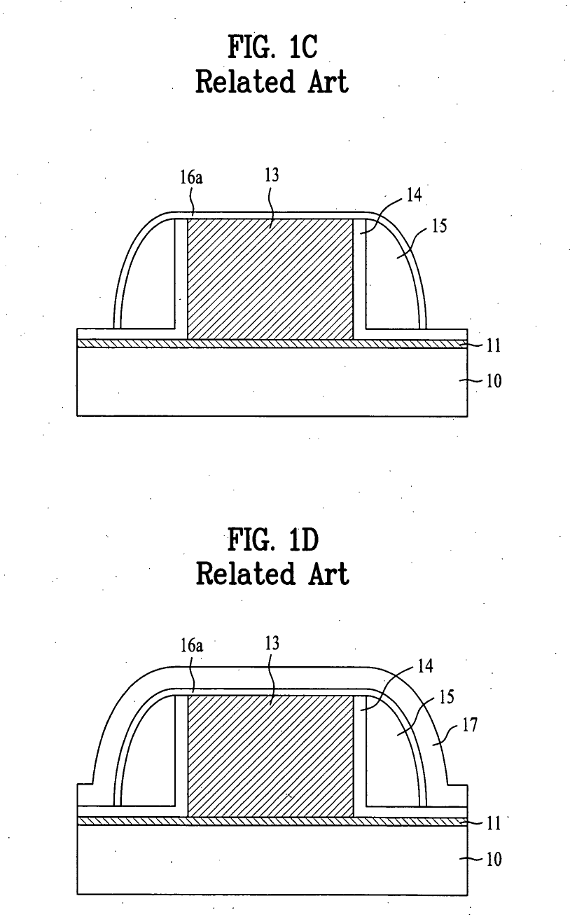

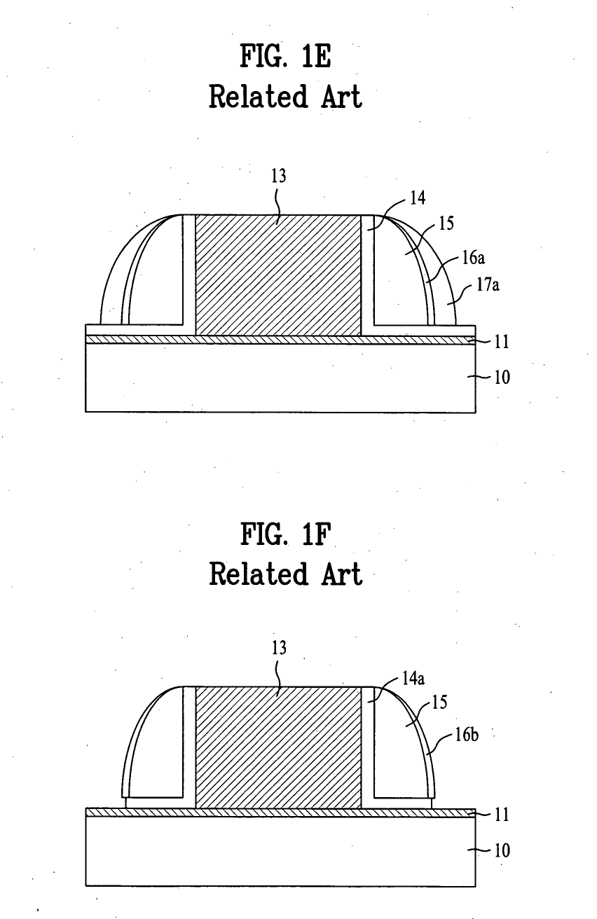

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

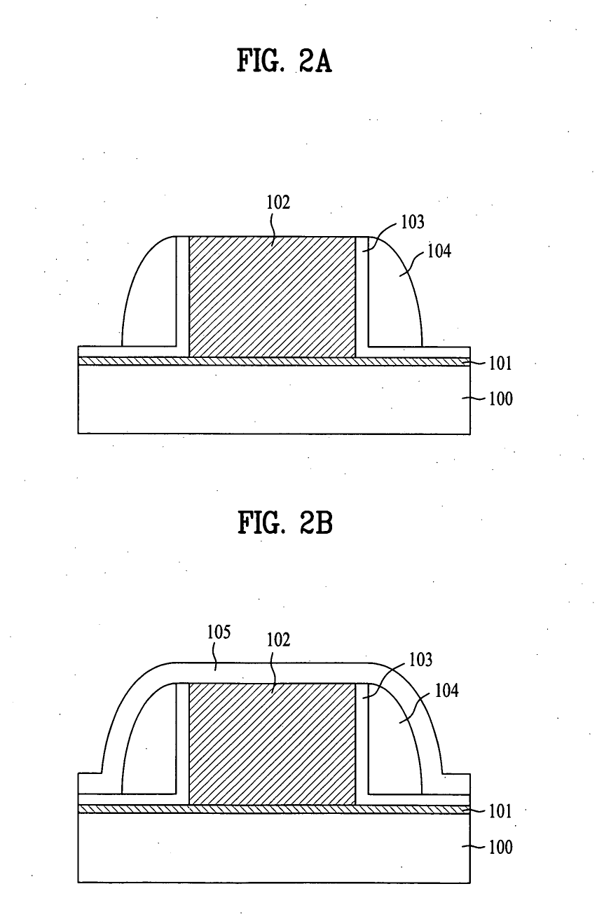

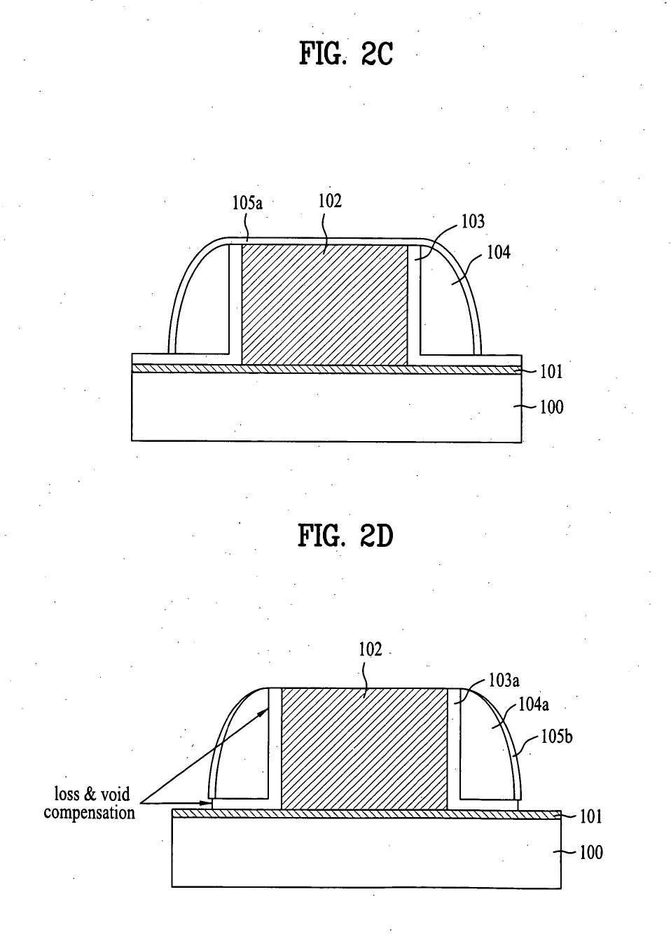

FIGS. 2A-2D illustrate a semiconductor fabricating method according to an exemplary embodiment of the present invention.

Referring to FIG. 2A, a gate insulating layer 101 is deposited on a substrate 100. A polysilicon gate 102 is formed on a predetermined portion of the gate insulating layer 101. A first spacer 103 is formed on a sidewall of the polysilicon gate 102 and the gate insulating layer 101 that is not overlapped with the polysilicon gate 102. The first spacer 103 may be formed by low-pressure tetra-ethyl-ortho-silicate deposition. Source/drain regions (not shown) are formed on the substrate 100 at opposite sides of the polysilicon gate 102. A second spacer 104 may be deposited on the first spacer 103 to be overlapped with lateral sides of the polysilicon gate 102. The second spacer 104 may be formed of silicon nitride (SiN).

Referring to FIG. 2B, an insulating interlayer 105 is deposited over the substrate 100 including the polysilicon gate 102 and the first and second spacers 103 and 104. The insulating interlayer 105 may be formed by plasma-enhanced tetra-ethyl-ortho-silicate deposition.

Referring to FIG. 2C, a dry etch process is carried out on the insulating interlayer 105 using a predetermined mask defining a salicide area and a non-salicide area to reduce the thickness of the insulating interlayer 105. Polymer generation is carried out on a sidewall of the second spacer 104 to form a shoulder 105a that prevents a loss caused by wet etching, which undercuts of the oxide layer, namely, the first spacer and the gate insulating layer. The dry echant is a gas mixture of oxygen (O2), argon (Ar), carbon tetrafluoride (CF4), difluoromethane (CH2F2), and trifluormethane (CHF3), where the etchant flow rates are approximately 80-180 sccm (O2), approximately 10-100 sccm (Ar), approximately 0-25 sccm (CF4), approximately 5-20 sccm (CH2F2), and approximately 10-40 sccm (CHF3). After completion of the dry etching process, the insulating interlayer 105 remains as a shoulder 105a on a lateral side of the second spacer 104 but in all other areas remains as a very thin layer or is entirely removed.

Referring to FIG. 2D, wet etch is carried out on the insulating interlayer 105a and on first spacer 103. Portions of the insulating interlayer 105a and of the first spacer 103 are removed during the wet etch. After the wet etch, the first and second sidewall spacers 103a and 104a provided to the sidewalls of the polysilicon gate 102 and insulating layer 105b are left. Since the first spacer material 103 and the insulating interlayer 105a are formed of the same material, i.e., plasma-enhanced tetra-ethyl-ortho-silicate, they remain as the first sidewall spacer 103a and insulating interlayer 105b on both lateral sides of the polysilicon gate 102 after completion of an isotropic wet etching process. Hence, the first sidewall spacer 103a over the substrate 100 is etched to be indented inwardly from the insulating interlayer 105b on the second sidewall spacer 104a.

As mentioned in the foregoing description, in fabricating the semiconductor device according to the method of the related art includes the re-deposition of related art the second insulating interlayer. In the method according to an exemplary embodiment of the present invention, on the other hand, the polymer generation may be carried out on the sidewall area by dry etching without the re-deposition of the insulating interlayer, thereby the loss caused by the undercut occurring during wet etching can be compensated. Wet etching is required in fabricating a semiconductor device to remove from the salicide area the insulating interlayer deposited to cover the non-salicide area. By adopting the semiconductor device fabrication method according to the present invention, however, the step of re-depositing the insulating interlayer to prevent the loss caused by undercut in wet etch may be eliminated. In the present invention, the shoulder may be provided to the sidewall spacer by the polymer generation during dry etching to prevent the wet etch attack into the salicide area and the void, thereby realizing a more stable device by enabling stable salicide and non-salicide areas. Additionally, since the re-deposition and etch of the insulating interlayer are skipped, the process is simplified and production costs are reduced.

It will be apparent to those skilled in the art that various modifications and variations can be made in the present invention without departing from the spirit or scope of the invention. Thus, it is intended that the present invention covers such modifications and variations provided they come within the scope of the appended claims and their equivalents.

What is claimed is:

1. A method of fabricating a semiconductor device, comprising:
forming a gate on a predetermined area of a substrate;
forming a spacer insulating layer on sidewalls of the gate;
forming an insulating interlayer over the substrate, including the gate and the spacer insulating layer;
simultaneously carrying out polymer generation on a lateral side of the spacer and a dry etching process on the insulating interlayer; and
leaving a sidewall spacer on both of the sidewalls of the polysilicon gate by performing wet etching to the insulating interlayer and the spacer insulating layer.

2. The method of claim 1, wherein the polymer generation and the dry etch use a gas mixture of O2, Ar, CF4, CH2F2, and CHF3.

3. The method of claim 2, wherein the O2 is supplied at a rate of approximately 80-180 sccm.

4. The method of claim 2, wherein the Ar is supplied at a rate of approximately 10-100 sccm.

5. The method of claim 2, wherein the CF4 is supplied at a rate of approximately 0-25 sccm.

6. The method of claim 2, wherein the CH2F2 is supplied at a rate of approximately 5-20 sccm.

7. The method of claim 2, wherein the CHF3 is supplied at a rate of approximately 10-40 sccm.

8. The method of claim 1, wherein the spacer insulating layer comprises an oxide layer formed on the sidewalls of the gate and the substrate, and a nitride layer formed on the oxide layer over the sidewalls of the gate.

9. The method of claim 1, wherein the insulating interlayer is formed of tetra-ethyl-ortho-silicate.

10. The method of claim 1, further comprising forming an oxide layer between the substrate and the gate.
